(19) United States
(12) Patent Application Publication
(10) Pub. No.: US 2008/0210461 A1
(43) Pub. Date: Sep. 4, 2008

(54) CIRCUIT BOARD WITH A THREE-TERMINAL JUMBER AND METHOD FOR FABRICATING THE SAME

(76) Inventors: Chien-Hung Chen, Keelung City (TW); Shu-Chih Chen, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/773,447

(22) Filed: Jul. 5, 2007

(30) Foreign Application Priority Data
Jul. 7, 2006 (CN) 200610098470.1

(51) Int. Cl. H05K 1/00; G06F 17/50; H01K 3/10

(52) U.S. Cl. 174/261; 716/11; 29/850

(57) ABSTRACT

A method of fabricating a circuit board includes the steps of: (a) defining a first jumper symbol and a second jumper symbol of a schematic circuit symbol library; (b) drawing the first jumper symbol and the second jumper symbol of the schematic circuit symbol library in a schematic circuit diagram for forming a three-terminal jumper symbol; (c) defining a first jumper pattern and a second jumper pattern of a PCB component pattern library; (d) calling the PCB component pattern library for drawing the first jumper pattern and the second jumper pattern in a PCB layout so as to define a three-terminal jumper pattern; (e) selecting a jumper symbol between the first jumper symbol and the second jumper symbol; and (f) mounting a jumper on the first jumper pattern or the second jumper pattern on the circuit board according to the PCB layout and a select result from step (e).

### BACKGROUND OF THE INVENTION

1. Field of the Invention

The invention relates to a method of fabricating a circuit board, and more particularly, to a method of fabricating a circuit board with a three-terminal jumper.

2. Description of the Prior Art

Jumpers are commonly utilized when electronic engineers develop circuit boards for cellular phones. Referring to FIG. 1 and FIG. 1, FIG. 1 illustrates a conventional I-shaped three-terminal jumper pattern 10 and FIG. 2 illustrates a conventional L-shaped three-terminal jumper pattern 12. The I-shaped three-terminal jumper pattern 10 includes three square sub-patterns 101, 102, 103, and the L-shaped three-terminal jumper pattern 12 also includes three square sub-patterns 121, 122, 123. In most circumstances, engineers from the SMT department are unaware that whether a device should be mounted on the square sub-patterns 101, 102, or sub-patterns 102, 103 of the I-shaped three-terminal jumper or on the sub-patterns 121, 122 or sub-patterns 122, 123 of the L-shaped three-terminal. As a result, electrical engineers from the research and development department must label the position of the jumper manually, which not only lowers the speed of the fabrication but also increases the chance of producing human errors.

### SUMMARY OF THE INVENTION

A method of fabricating a circuit board is disclosed, the method includes: (a) defining a first jumper symbol and a second jumper symbol of a schematic circuit symbol library; (b) drawing the first jumper symbol and the second jumper symbol of the schematic circuit symbol library in a schematic circuit diagram, wherein the first jumper symbol and the second jumper symbol form a three-terminal jumper symbol; (c) defining a first jumper pattern and a second jumper pattern of a printed circuit board component pattern library; (d) calling the printed circuit board component library for drawing the first jumper pattern and the second jumper pattern in a printed circuit board layout, wherein the first jumper pattern and the second jumper pattern form a three-terminal jumper pattern; (e) selecting a jumper symbol between the first jumper symbol and the second jumper symbol; and (f) mounting a jumper on the first jumper pattern or the second jumper pattern of the printed circuit board component pattern library according to the printed circuit board layout and a result selected from step (e).

A circuit board layout system is disclosed. The circuit board layout system includes: a schematic circuit diagram editing device, comprising: a schematic circuit symbol library having a first jumper symbol and a second jumper symbol; and a schematic circuit diagram user editing interface allowing users to select the first jumper symbol and the second jumper symbol from the schematic circuit symbol library and drawing the first jumper symbol and the second jumper symbol in a schematic circuit diagram, wherein the first jumper symbol and the second jumper symbol form a three-terminal jumper symbol; a printed circuit board layout editing device, comprising: a printed circuit board component pattern library having a first jumper pattern and a second jumper pattern; and a user layout editing interface allowing users to select the first jumper pattern and the second jumper pattern from the printed circuit board component pattern library and draw the first jumper pattern and the second jumper pattern in a printed circuit board layout, wherein the first jumper pattern and the second jumper pattern form a three-terminal jumper pattern; and

a jumper mounted on the first jumper pattern or the second jumper pattern of the three-terminal jumper pattern according to the printed circuit board layout and a select result from the first jumper symbol and the second jumper symbol.

A printed circuit board layout editing device is disclosed, wherein the printed circuit board layout editing device controls a jumper disposed on a circuit board according to information provided by a schematic circuit diagram editing device, wherein the schematic circuit diagram editing device comprises a schematic circuit symbol library having a first jumper symbol and a second jumper symbol and a schematic circuit diagram user editing interface allowing users to select the first jumper symbol and the second jumper symbol from the schematic circuit symbol library and drawing the first jumper symbol and the second jumper symbol in a schematic circuit diagram, such that the first jumper symbol and the second jumper symbol form a three-terminal jumper symbol, the printed circuit board layout editing device comprising: a printed circuit board component pattern library having a first jumper pattern and a second jumper pattern; and a user layout editing interface allowing users to select the first jumper pattern and the second jumper pattern from the printed circuit board component pattern library and draw the first jumper pattern and the second jumper pattern in a printed circuit board layout, wherein the first jumper pattern and the second jumper pattern form a three-terminal jumper pattern; wherein the jumper is mounted on the first jumper pattern or the second jumper pattern of the three-terminal jumper pattern according to the printed circuit board layout and a select result from the first jumper symbol and the second jumper symbol.

A method for fabricating a circuit board is disclosed, in which the method includes: (a) drawing a default short jumper symbol and a default open jumper symbol into a schematic circuit diagram, and combining the default short jumper symbol and the default open jumper symbol to form a three-terminal jumper symbol, wherein the setting of the three-terminal jumper symbol corresponding to the default short jumper symbol is electrically closed and the setting of the three-terminal jumper symbol corresponding to the default open jumper symbol is electrically open; (b) drawing the default short jumper pattern and the default open jumper pattern into a circuit board layout to form a three-terminal jumper pattern in the circuit board layout, the default short jumper pattern being corresponding to the default short jumper symbol, and the default open jumper pattern being corresponding to the default open jumper symbol, so that the three-terminal jumper pattern being corresponding to the three-terminal jumper symbol; and (c) mounting a jumper at the position of a circuit board where the default short jumper pattern of the three-terminal jumper pattern is drawn, and setting electrically open at the position of the circuit board where the default open jumper pattern of the three-terminal jumper pattern is drawn.

A schematic circuit diagram editing device is disclosed. The schematic circuit diagram editing device includes a schematic circuit symbol library having a default short jumper symbol and a default open jumper symbol; and a schematic circuit diagram user editing interface allowing users to select the default short jumper symbol and the default open jumper symbol from the schematic circuit symbol library and draw the default short jumper symbol and the default open jumper symbol in a schematic circuit diagram, wherein when the default short jumper symbol and the default open jumper symbol are combined, the default short jumper symbol and the default open jumper symbol would form a three-terminal jumper symbol; wherein the default setting of the three-terminal jumper symbol corresponding to the default short jumper symbol is electrically closed and the default setting of the three-terminal jumper symbol corresponding to the default open jumper symbol is electrically open.

A printed circuit board user editing device is disclosed. The printed circuit board user editing interface includes a printed circuit board component pattern library having a default short jumper pattern and a default open jumper pattern; and a user layout editing interface allowing users to select the default short jumper pattern and the default open jumper pattern from the printed circuit board component pattern library for outlining a circuit board layout, wherein when the default short jumper pattern and the default open jumper pattern are combined, the default short jumper pattern and the default open jumper pattern would form a three-terminal jumper pattern; wherein the default setting of the three-terminal jumper pattern corresponding to the default short jumper symbol is electrically closed and the default setting of the three-terminal jumper pattern corresponding to the default open jumper symbol is electrically open.

A printed circuit board is disclosed. The printed circuit board includes a first jumper pattern having a first sub-pattern and a second sub-pattern; and a second jumper pattern having a third sub-pattern and a fourth sub-pattern, wherein the first jumper pattern and the second jumper pattern combined to form a three-terminal jumper pattern; wherein the second sub-pattern and the fourth sub-pattern are combined to form a jointly formed pattern while the first jumper pattern and the second jumper pattern are combined to form the three-terminal jumper pattern.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an I-shaped three-terminal jumper pattern according to the prior art.

FIG. 2 illustrates an L-shaped three-terminal jumper pattern according to the prior art.

FIG. 3 is a block diagram illustrating the function of a circuit board layout system according to the present invention.

FIG. 4 is a flow chart illustrating the process of mounting a jumper on the circuit board according to the present invention.

FIG. 5 illustrates a circuit diagram of a three-terminal jumper symbol according to an embodiment of the present invention.

FIG. 6 illustrates a schematic view of combining a first jumper pattern and a second jumper pattern into a three-terminal jumper pattern according to the present invention.

FIGS. 7-9 illustrates a three-terminal jumper pattern combined from the first jumper pattern and the second jumper pattern according to an embodiment of the present invention.

FIG. 10 is a flow chart illustrating the process of mounting the jumper on the circuit board according to an embodiment of the present invention.

FIG. 11 illustrates a circuit diagram of a three-terminal jumper symbol according to an embodiment of the present invention.

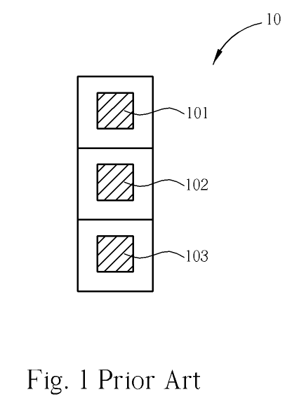

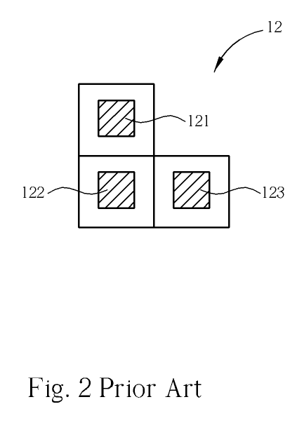

### DETAILED DESCRIPTION

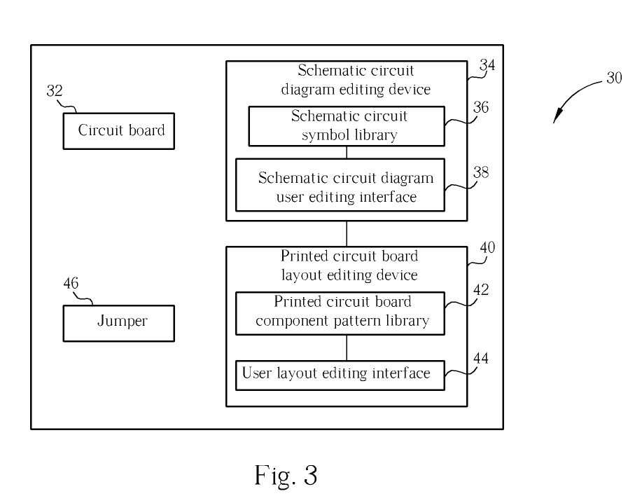

Referring to FIG. 3, FIG. 3 is a block diagram illustrating the function of a circuit board layout system 30 according to the present invention. The circuit board layout system 30 includes a schematic circuit diagram editing device 34 and a printed circuit board layout editing device 40, in which the schematic circuit diagram editing device 34 has a schematic circuit symbol library 36 and a schematic circuit diagram user editing interface 38. The schematic circuit diagram user editing interface 38 allows users to select jumper symbols from the schematic circuit symbol library 36 and draw the selected symbols into a schematic circuit diagram. The printed circuit board layout editing device 40 includes a printed circuit board component pattern library 42 and a user layout editing interface 44, in which the user layout editing interface 44 allows users to select jumper patterns from the printed circuit board component pattern library 42 and draw the selected patterns into a printed circuit board layout. The schematic circuit diagram editing device 34 and the printed circuit board layout editing device 40 normally are implemented by software. Consequently, the jumper patterns will be printed on the circuit board 32 according to the schematic circuit diagram and the circuit board layout output from the circuit board layout system 30. When the circuit board is fabricated in the factory, a jumper 46 will be mounted on the circuit board 32 where the jumper pattern is printed

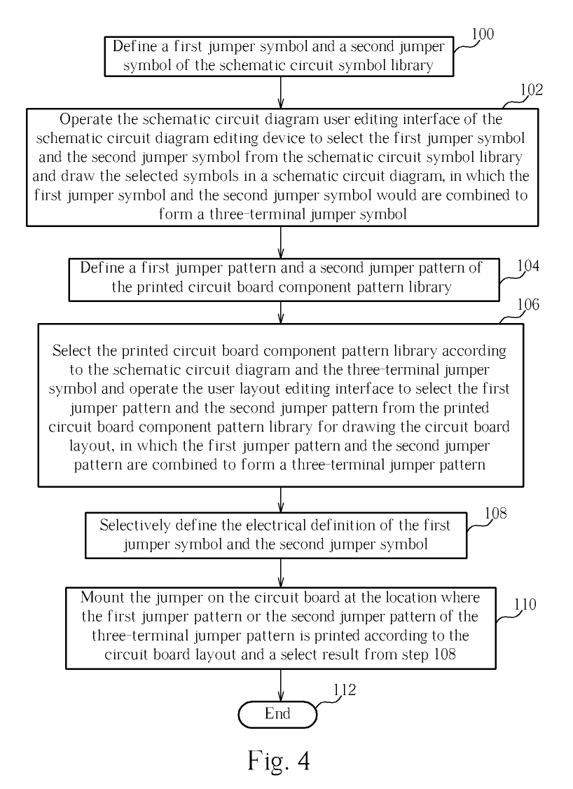

Referring to FIG. 4, FIG. 4 is a flow chart illustrating the process of mounting a jumper 46 on the circuit board 32. The process includes the following steps:

Step 100: Define a first jumper symbol and a second jumper symbol of the schematic circuit symbol library 36.

Step 102: Operate the schematic circuit diagram user editing interface 38 of the schematic circuit diagram editing device 34 to select the first jumper symbol and the second jumper symbol from the schematic circuit symbol library 36 and draw the selected symbols in a schematic circuit diagram, in which the first jumper symbol and the second jumper symbol are combined to form a three-terminal jumper symbol.

Step 104: Define a first jumper pattern and a second jumper pattern of the printed circuit board component pattern library 42, in which the first jumper pattern of the circuit board layout corresponds to the first jumper symbol of the schematic circuit diagram and the second jumper pattern of the circuit board layout corresponds to the second jumper symbol of the schematic circuit diagram.

Step 106: According to the schematic circuit diagram and the three-terminal jumper symbol, select the printed circuit board component pattern library 42, and then operate the user layout editing interface 44 to select the first jumper pattern and the second jumper pattern from the printed circuit board component pattern library 42 and draw the selected patterns in the circuit board layout, in which the first jumper pattern and the second jumper pattern would form a three-terminal jumper pattern and this three-terminal jumper pattern of the circuit board layout would correspond to the three-terminal jumper symbol of the schematic circuit diagram.

Step 108: Selectively define the electrical definition of the first jumper symbol and the second jumper symbol, such as defining the first jumper symbol as short circuit and defining the second jumper symbol as open circuit.

Step 110: Mount the jumper 46 on the circuit board 32 at the location where the first jumper pattern or the second jumper pattern of the three-terminal jumper pattern is printed. For example: if the first jumper symbol is defined as “short circuit” in step 108, then the jumper 46 is disposed at the location where the first jumper pattern is printed

Step 112: End.

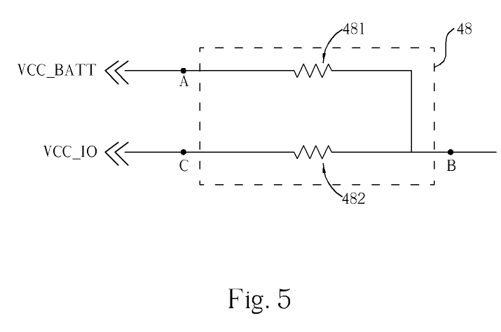

Referring to FIG. 5, FIG. 5 illustrates a circuit diagram of a three-terminal jumper symbol 48 according to an embodiment of the present invention. The three-terminal jumper symbol 48 includes three electrical junctions A, B, and C. Preferably, two settings can be predetermined for the junctions of the three-terminal jumper symbol 48. For instance, the junction between A-B can be set as closed and the junction between B-C can be set as open, or the junction between A-B can be set as open and the junction between B-C can be set as closed.

First, a first jumper symbol 481 and a second jumper symbol 482 of the schematic circuit symbol library 36 can be defined, in which each of the first jumper symbol 481 and the second jumper symbol 482 could represent a different electrical device.

Electronic engineers could then use the schematic circuit diagram user editing interface 38 of the schematic circuit diagram editing device 34 to select the first jumper symbol 481 and the second jumper symbol 482 from the schematic circuit symbol library 36 for drawing the schematic circuit diagram shown in FIG. 5, in which the first jumper symbol 481 and the second jumper symbol 482 would be combined to form a three-terminal jumper symbol 48. At this moment, none of the first jumper symbol 481 or the second jumper symbol 482 is assigned as a short circuit or an open circuit.

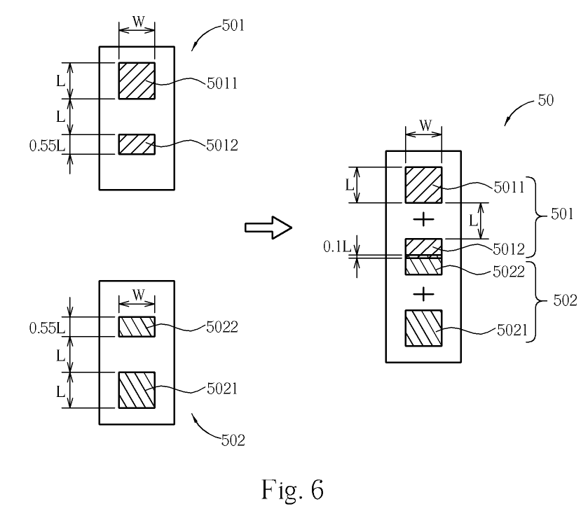

Referring to FIG. 6, FIG. 6 illustrates a schematic view of combining a first jumper pattern 501 and a second jumper pattern 502 into a three-terminal jumper pattern 50 according to the present invention. Preferably, a first jumper pattern 501 and a second jumper pattern 502 of the printed circuit board component pattern library 42 can be defined, in which the first jumper pattern 501 corresponds to the first jumper symbol 481 and represents the electrical connection for the junction A-B, and the second jumper pattern 502 corresponds to the second jumper symbol 482 and represents the electrical connection for the junction B-C.

Electronic engineers could then use the user layout editing interface 44 of the printed circuit board component pattern library 42 to select the first jumper pattern 501 and the second jumper pattern 502 from the printed circuit board component pattern library and draw the selected patterns in the circuit board layout, in which the first jumper pattern 501 and the second jumper pattern 502 are combined to form a three-terminal jumper pattern 50.

In this embodiment, the three-terminal jumper pattern 50 shown in FIG. 6 is an I-shaped three-terminal jumper pattern, in which the first jumper pattern 501 includes a first sub-pattern 5011 and a second sub-pattern 5012 and the second jumper pattern 502 includes a third sub-pattern 5021 and a fourth sub-pattern 5022. The first sub-pattern 5011 is substantially the same as the third sub-pattern 5021 and the second sub-pattern 5012 is substantially the same as the fourth sub-pattern 5022. The first jumper pattern 501 and the second jumper pattern 502 can be combined to form an I-shaped three-terminal jumper pattern having adequate area. For instance, if the length of the first sub-pattern 5011 and the third sub-pattern 5021 is L and the width of the first sub-pattern 5011 and the third sub-pattern 5021 is W, and the length of the second sub-pattern 5012 and the fourth sub-pattern 5022 is 0.55 L and the width of the second sub-pattern 5012 and the fourth sub-pattern 5022 is W, the combined area of the second sub-pattern 5012 and the fourth sub-pattern 5022 would be substantially equal to the area of either the first sub-pattern 5011 or the third sub-pattern 5021. The overlapped area between the second sub-pattern 5012 and the fourth sub-pattern 5022 is 0.1 L×W. Preferably, an I-shaped three-terminal jumper pattern having three squares can be formed, in which the area of each square pattern is L×W and the range of L is 4≦L≦30 (mil) and the range of W is 12≦W≦125 (mil). Ultimately, the combined pattern of the first jumper pattern 501 and the second jumper pattern 502 is positioned between the first sub-pattern 5011 and the third sub-pattern 5021 and arranged according to a straight line, thereby forming the three-terminal jumper pattern 50 into an I-shaped three-terminal jumper pattern.

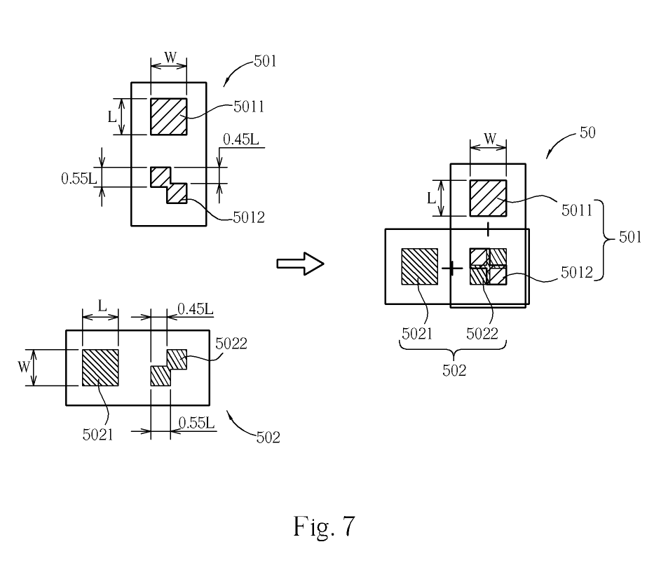

Additionally, the jumper pattern 50 can also be patterns having other shapes, such as an L-shaped three-terminal jumper pattern. Referring to FIG. 7, FIG. 7 illustrates a three-terminal jumper pattern 50 combined from the first jumper pattern 501 and the second jumper pattern 502 according to an embodiment of the present invention. In this embodiment, the three-terminal jumper pattern 50 is an L-shaped three-terminal jumper pattern, in which the first sub-pattern 5011 is the same as the third sub-pattern 5021 and the second sub-pattern 5012 is the same as the fourth sub-pattern 5022. The first jumper pattern 501 and the second jumper pattern 502 can be combined to form an L-shaped three-terminal jumper pattern having different sizes. For instance, the length and width of the first sub-pattern 5011 and the third sub-pattern 5021 are L and W respectively, and each of the second sub-pattern 5012 and the fourth sub-pattern 5022 being a rectangle having two squares cut off diagonally, in which the width of each square is 0.45 L. The first jumper pattern 501 and the second jumper pattern 502 are then overlapped vertically according to a 90 degree angle to form a three-terminal jumper pattern 50. The combined area of the second sub-pattern 5012 and the fourth sub-pattern 5022 is substantially the same as the area of each of the first sub-pattern 5011 and the third sub-pattern 5021. The overlapped area of the second sub-pattern 5012 and the fourth sub-pattern 5022 is 2 L×W−4(0.45 L)². By doing so, an L-shaped three-terminal jumper pattern having three square patterns can be formed, in which the area of each square pattern is L×W and the range of L is 4≦L≦30 (mil) and the range of W is 12≦W≦125 (mil). Ultimately, the combined pattern of the first jumper pattern 501 and the second jumper pattern 502 is positioned between the first sub-pattern 5011 and the third sub-pattern 5021 and arranged according to an L-shape, such that the three-terminal jumper pattern 50 would form into an L-shaped three-terminal jumper pattern.

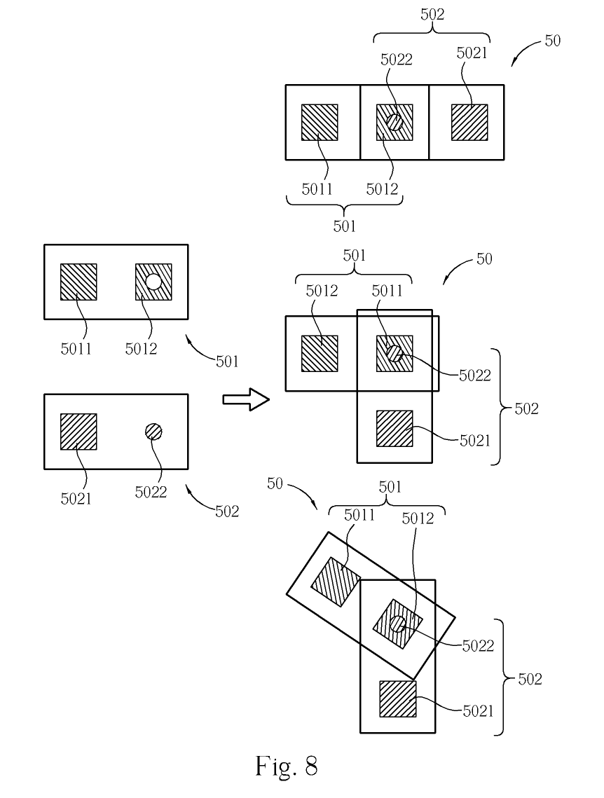

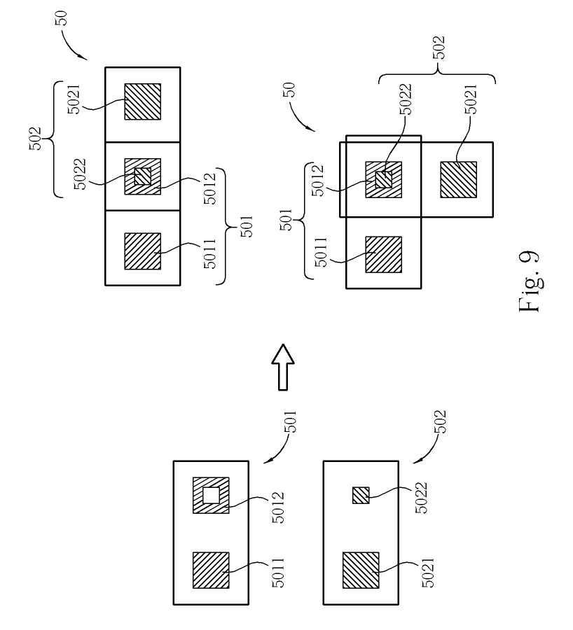

In addition to the shapes disclose in the aforementioned embodiments, the three-terminal jumper pattern 50 can also be composed of other shapes. Referring to FIG. 8 and FIG. 9, FIG. 8 and FIG. 9 are schematic views illustrating a three-terminal jumper pattern 50 combined from the first jumper pattern 501 and the second jumper pattern 502 according to an embodiment of the present invention. For instance, the first jumper pattern 501 and the second jumper pattern 502 can be stacked on top of each other according to a vertical or horizontal direction to form an I-shaped or L-shaped three-terminal jumper pattern. Moreover, as shown in FIG. 8, while the second sub-pattern 5012 of the first jumper pattern 501 is a ring having an opening and the fourth sub-pattern 5022 of the second jumper pattern 502 is an circle that fits into the opening of the ring, a pattern can be formed by surrounding the fourth sub-pattern 5022 with the second sub-pattern 5012. The first jumper pattern 501 and the second jumper pattern 502 can also be combined to form a three-terminal jumper pattern 50 having an included angle. For instance, a combined pattern of the first jumper pattern 501 and the second jumper pattern 502 can be positioned between the first sub-pattern 5011 and the third sub-pattern 5021 to form a V-shaped arrangement, thereby forming a V-shaped three-terminal jumper pattern.

Next, electronic engineers could define the status of the first jumper symbol 481 and the second jumper symbol 482, such as which symbol represents a short circuit and which symbol represents a open circuit, thereby determining which two junction within the three-terminal jumper is closed and which two junction within the three-terminal jumper is open. The selected jumper symbol and definition corresponding to each symbol are listed in a Bill of Material form or reported by an SMD placement program. SMT engineers would realize whether the jumper 46 is to be placed on the circuit board 32 corresponding to the first jumper pattern 501 or the second jumper pattern 502 of the three-terminal jumper pattern 50.

For instance, as shown in FIG. 6, when an electronic engineer wishes to mount two ends of the jumper 46 on the square patterns positioned on the upper and central region of the three-terminal jumper pattern 50, such as having a short circuit between the junction A-B and an open circuit between the junction B-C, the electronic engineer could define the first jumper symbol 481 corresponding to the first jumper pattern 501 as short circuit and record this definition in the symbol definition of the bill of material. SMT engineers would then mount two ends of the jumper 46 on the square patterns positioned on the upper and central region of the three-terminal jumper pattern 50 according to the definition recorded in the bill of material form and the circuit board layout. The mounting process could be a typical surface mounting technique. Preferably, this fabrication process enables the SMD process conducted in the later stage to decide the mounting position of the jumper 46, thereby increasing the flexibility of the overall flow.

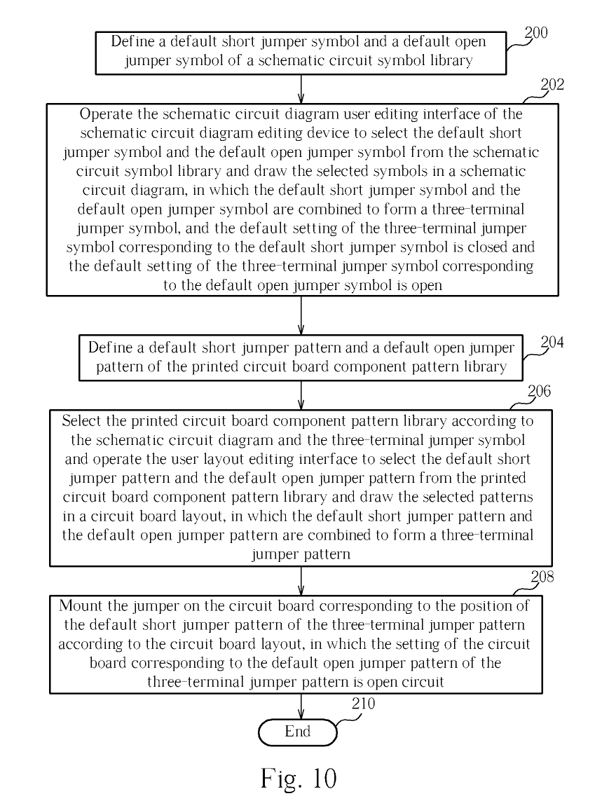

According to an embodiment of the present invention, the status for each jumper symbol can also be assigned while the schematic circuit diagram is outlined. By doing so, the mounting position of each jumper 46 on the circuit board 32 is determined accordingly. Referring to FIG. 10, FIG. 10 is a flow chart illustrating the process of mounting the jumper 46 on the circuit board 32 according to an embodiment of the present invention. The process includes the following steps:

Step 200: Define a default short jumper symbol and a default open jumper symbol of a schematic circuit symbol library.

Step 202: Operate the schematic circuit diagram user editing interface 38 of the schematic circuit diagram editing device 34 to select the default short jumper symbol and the default open jumper symbol from the schematic circuit symbol library 36 and draw the selected symbols in a schematic circuit diagram, in which the default short jumper symbol and the default open jumper symbol are combined to form a three-terminal jumper symbol, and the default setting of the three-terminal jumper symbol corresponding to the default short jumper symbol is closed and the default setting of the three-terminal jumper symbol corresponding to the default open jumper symbol is open.

Step 204: Define a default short jumper pattern and a default open jumper pattern of the printed circuit board component pattern library 42.

Step 206: Select the printed circuit board component pattern library 42 according to the schematic circuit diagram and the three-terminal jumper symbol and operate the user layout editing interface 44 to select the default short jumper pattern and the default open jumper pattern from the printed circuit board component pattern library 42 and draw the selected patterns in a circuit board layout, in which the default short jumper pattern and the default open jumper pattern are combined to form a three-terminal jumper pattern.

Step 208: Mount the jumper 46 on the circuit board 32 corresponding to the default short jumper pattern of the three-terminal jumper pattern according to the circuit board layout, in which the setting of the circuit board corresponding to the default open jumper pattern is open circuit.

Step 210: End

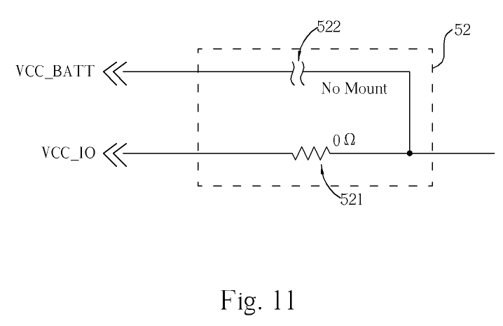

The aforementioned process is further discussed in detail below. Referring to FIG. 11, FIG. 11 illustrates a circuit diagram of a three-terminal jumper symbol 52 according to an embodiment of the present invention. First, a default short jumper symbol 521 and a default open jumper symbol 522 of the schematic circuit symbol library 36 can be defined, in which the default setting for the default short jumper symbol 521 is closed circuit and the default setting for the default open jumper symbol 522 is open circuit. In other words, the default short jumper symbol 521 can be a resistor symbol having 0 ohms and the default open jumper symbol 522 can be an open circuit symbol. Electronic engineers could then use the schematic circuit diagram user editing interface 38 of the schematic circuit diagram editing device 34 to select the default short jumper symbol 521 and the default open jumper symbol 522 from the schematic circuit symbol library 36 and draw the selected symbols in the circuit diagram shown in FIG. 11. The default short jumper symbol 521 and the default open jumper symbol 522 are then combined to form the three-terminal jumper symbol 52. By doing so, the status of each jumper is predefined and the mounting location for the jumper 46 on the circuit board 32 is also predetermined before the schematic circuit diagram is completed.

Next, the default short jumper pattern and the default open jumper pattern of the printed circuit board component pattern library 42 are defined, in which the default open jumper pattern would correspond to the default short jumper symbol 521 and the default open jumper pattern would correspond to the default open jumper symbol 522. Subsequently, the printed circuit board component pattern library 42 is called according to the three-terminal jumper symbol 52 within the circuit diagram shown in FIG. 11 and the user layout editing interface 44 of the printed circuit board component pattern library 42 is used to select the default short jumper pattern and the default open jumper pattern from the printed circuit board component pattern library 42 and draw the selected patterns in the circuit board layout, in which the default short jumper pattern and the default open jumper pattern are combined to form the three-terminal jumper pattern. The default short jumper pattern, the default open jumper pattern, and the three-terminal jumper pattern can be the same as the first jumper pattern 501, the second jumper pattern 502, and the three-terminal jumper pattern 50 shown in FIGS. 6-9, which are all within the scope of the present invention.

In this embodiment, since the status (such as the circuit being open or closed) is pre-defined by the drafting engineer, the electronic engineer does not have to choose the jumper symbol personally. Thereafter, SMT operators would then mount the two ends of the jumper 46 on the corresponding location of the default short jumper pattern according to the circuit board layout information. Preferably, the mounting process can be a typical surface mount technique.

In contrast to the conventional method for fabricating circuit boards, the present invention allows SMT engineers to obtain the mounting position of the jumper by just confirming the product specification, the SMD layout program, or the schematic circuit diagram. Hence, no additional operators are assigned to confirm the location of the jumper. By using this approach, the present invention could improve problems caused by assigning electronic engineers to label the position of the jumpers and pass the mounting information to the SMT engineers manually, thereby increasing the efficiency of the fabrication process and minimizing the occurrence of human error.

Those skilled in the art will readily observe that numerous modifications and alterations of the device and method may be made while retaining the teachings of the invention.

What is claimed is:

1. A method for fabricating a circuit board, comprising:
(a) drawing a default short jumper symbol and a default open jumper symbol into a schematic circuit diagram, and combining the default short jumper symbol and the default open jumper symbol to form a three-terminal jumper symbol, wherein the setting of the three-terminal jumper symbol corresponding to the default short jumper symbol is electrically closed and the setting of the three-terminal jumper symbol corresponding to the default open jumper symbol is electrically open;
(b) drawing the default short jumper pattern and the default open jumper pattern into a circuit board layout to form a three-terminal jumper pattern in the circuit board layout, the default short jumper pattern being corresponding to the default short jumper symbol, and the default open jumper pattern being corresponding to the default open jumper symbol, so that the three-terminal jumper pattern being corresponding to the three-terminal jumper symbol; and
(c) mounting a jumper at the position of a circuit board where the default short jumper pattern of the three-terminal jumper pattern is drawn, and setting electrically open at the position of the circuit board where the default open jumper pattern of the three-terminal jumper pattern is drawn.

2. The method of claim 1, wherein the default short jumper pattern comprises a first sub-pattern and a second sub-pattern, the default open jumper pattern comprises a third sub-pattern and a fourth sub-pattern, such that the second sub-pattern and the fourth sub-pattern are combined to form a jointly formed pattern while the default short jumper pattern and the default open jumper pattern are combined to form the three-terminal jumper pattern.

3. The method of claim 2, wherein the area of the jointly formed pattern is equivalent to the area of the first sub-pattern.

4. The method of claim 2, wherein the second sub-pattern is different from the fourth sub-pattern, and the shape of the jointly formed pattern is equivalent to the shape of the first sub-pattern.

5. The method of claim 2, wherein the jointly formed pattern is positioned between the first sub-pattern and the third sub-pattern and arranged according to a straight line, such that the three-terminal jumper pattern is an I-shaped three-terminal jumper pattern.

6. The method of claim 2, wherein the jointly formed pattern is positioned between the first sub-pattern and the third sub-pattern and arranged according to an L-shape, such that the three-terminal jumper pattern is an L-shaped three-terminal jumper pattern.

7. The method of claim 2, wherein the jointly formed pattern is positioned between the first sub-pattern and the third sub-pattern and arranged according to a V-shape, such that the three-terminal jumper pattern is a V-shaped three-terminal jumper pattern.

8. The method of claim 2, wherein the second sub-pattern is a ring-shaped pattern, the fourth sub-pattern is a circular pattern, and the second sub-pattern surrounds the fourth sub-pattern for forming the jointly formed pattern.

9. A schematic circuit diagram editing device, comprising:
a schematic circuit symbol library having a default short jumper symbol and a default open jumper symbol; and
a schematic circuit diagram user editing interface allowing users to select the default short jumper symbol and the default open jumper symbol from the schematic circuit symbol library and draw the default short jumper symbol and the default open jumper symbol in a schematic circuit diagram, wherein when the default short jumper symbol and the default open jumper symbol are combined, the default short jumper symbol and the default open jumper symbol form a three-terminal jumper symbol;
wherein the default setting of the three-terminal jumper symbol corresponding to the default short jumper symbol is electrically closed and the default setting of the three-terminal jumper symbol corresponding to the default open jumper symbol is electrically open.

10. A printed circuit board user editing device, comprising:
a printed circuit board component pattern library having a default short jumper pattern and a default open jumper pattern; and
a user layout editing interface allowing users to select the default short jumper pattern and the default open jumper pattern from the printed circuit board component pattern library for outlining a circuit board layout, wherein when the default short jumper pattern and the default open jumper pattern are combined, the default short jumper pattern and the default open jumper pattern form a three-terminal jumper pattern;
wherein the default setting of the three-terminal jumper pattern corresponding to the default short jumper symbol is electrically closed and the default setting of the three-terminal jumper pattern corresponding to the default open jumper symbol is electrically open.

11. The printed circuit board user editing device of claim 10, wherein the default short jumper pattern comprises a first sub-pattern and a second sub-pattern, the default open jumper pattern comprises a third sub-pattern and a fourth sub-pattern, such that the second sub-pattern and the fourth sub-pattern are combined to form a jointly formed pattern while the default short jumper pattern and the default open jumper pattern are combined to form the three-terminal jumper pattern.

12. The printed circuit board user editing device of claim 11, wherein the area of the jointly formed pattern is equivalent to the area of the first sub-pattern.

13. The printed circuit board user editing device of claim 11, wherein the second sub-pattern is different from the fourth sub-pattern, and the shape of the jointly formed pattern is equivalent to the shape of the first sub-pattern.

14. The printed circuit board user editing device of claim 11, wherein the jointly formed pattern is positioned between the first sub-pattern and the third sub-pattern and arranged according to a straight line, such that the three-terminal jumper pattern is an I-shaped three-terminal jumper pattern.

15. The printed circuit board user editing device of claim 11, wherein the jointly formed pattern is positioned between the first sub-pattern and the third sub-pattern and arranged according to an L-shape, such that the three-terminal jumper pattern is an L-shaped three-terminal jumper pattern.

16. The printed circuit board user editing device of claim 11, wherein the jointly formed pattern is positioned between the first sub-pattern and the third sub-pattern and arranged according to a V-shape, such that the three-terminal jumper pattern is a V-shaped three-terminal jumper pattern.

17. The printed circuit board user editing device of claim 11, wherein the second sub-pattern is a ring-shaped pattern, the fourth sub-pattern is a circular pattern, and the second sub-pattern surrounds the fourth sub-pattern for forming the jointly formed pattern.

18. A printed circuit board, comprising:
a first jumper pattern having a first sub-pattern and a second sub-pattern; and
a second jumper pattern having a third sub-pattern and a fourth sub-pattern, wherein the first jumper pattern and the second jumper pattern combined to form a three-terminal jumper pattern;
wherein the second sub-pattern and the fourth sub-pattern are combined to form a jointly formed pattern while the first jumper pattern and the second jumper pattern are combined to form the three-terminal jumper pattern.

19. The printed circuit board of claim 18, wherein the area of the jointly formed pattern is equivalent to the area of the first sub-pattern.

20. The printed circuit board of claim 18, wherein the second sub-pattern is different from the fourth sub-pattern, and the shape of the jointly formed pattern is equivalent to the shape of the first sub-pattern.

21. The printed circuit board of claim 18, wherein the jointly formed pattern is positioned between the first sub-pattern and the third sub-pattern and arranged according to a straight line, such that the three-terminal jumper pattern is an I-shaped three-terminal jumper pattern.

22. The printed circuit board of claim 18, wherein the jointly formed pattern is positioned between the first sub-pattern and the third sub-pattern and arranged according to an L-shape, such that the three-terminal jumper pattern is an L-shaped three-terminal jumper pattern.

23. The printed circuit board of claim 18, wherein the jointly formed pattern is positioned between the first sub-pattern and the third sub-pattern and arranged according to a V-shape, such that the three-terminal jumper pattern is a V-shaped three-terminal jumper pattern.

24. The printed circuit board of claim 18, wherein the second sub-pattern is a ring-shaped pattern, the fourth sub-pattern is a circular pattern, and the second sub-pattern surrounds the fourth sub-pattern for forming the jointly formed pattern.

25. The printed circuit board of claim 18 further comprising a jumper disposed corresponding to the first sub-pattern and the jointly formed pattern, wherein the first sub-pattern and the jointly formed pattern comprises a short circuit and the third sub-pattern and the jointly formed pattern comprises an open circuit.
